(19) United States
(12) Patent Application Publication
(10) Pub. No.: US 2024/0282676 A1
(43) Pub. Date: Aug. 22, 2024

(54) SEMICONDUCTOR DEVICE

(71) Applicant: Rohm Co., Ltd., Kyoto-shi (JP)

(72) Inventors: Ryotaro KAKIZAKI, Kyoto-shi (JP); Yasumasa KASUYA, Kyoto-shi (JP); Koshun SAITO, Kyoto-shi (JP)

(21) Appl. No.: 18/649,331

(22) Filed: Apr. 29, 2024

Related U.S. Application Data
(63) Continuation of application No. PCT/JP2022/042795, filed on Nov. 18, 2022.

(30) Foreign Application Priority Data
Dec. 1, 2021 (JP) 2021-195178

(51) Int. Cl. H01L 23/495; H01L 23/00; H01L 23/31

(52) U.S. Cl. CPC H01L 23/49513; H01L 23/3107; H01L 23/49562; H01L 24/45; H01L 24/48; H01L 2224/45144; H01L 2224/48245; H01L 2924/13091

(57) ABSTRACT

A semiconductor device includes a semiconductor element, a lead and a sealing resin. The lead includes a die pad and terminal. The die pad includes a lead obverse surface facing a first side in a thickness direction for mounting the semiconductor element, and a lead reverse surface facing a second side in the thickness direction. The sealing resin includes a first resin surface facing the first side in the thickness direction, a second resin surface facing the second side in the thickness direction, and a third resin surface facing a first side in a first direction orthogonal to the thickness direction. The sealing covers resin the semiconductor element and a part of the die pad. The lead reverse surface includes a portion exposed from the second resin surface and located on the first side in the first direction from the third resin surface as viewed in the thickness direction.

### TECHNICAL FIELD

The present disclosure relates to a semiconductor device.

### BACKGROUND ART

JP-A-2017-174951 discloses an example of semiconductor device that includes a first lead including a first pad having a pad obverse surface and a pad reverse surface, a second lead, a third lead, a semiconductor element mounted on the pad obverse surface, and a sealing resin held in contact with the pad obverse surface and covering the semiconductor element. The first lead, the second lead and the third lead have a first terminal, a second terminal and a third terminal, respectively, that extend in the same direction. The semiconductor device is mounted on a circuit board or the like by inserting the first terminal, the second terminal and the third terminal into through-holes of the circuit board. When the semiconductor device is attached to a heat sink, an insulating sheet, for example, is placed between the pad reverse surface and the heat sink.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure.

FIG. 3 is a perspective view of the semiconductor device according to the first embodiment of the present disclosure.

FIG. 4 is a perspective view showing relevant portions of the semiconductor device according to the first embodiment of the present disclosure.

FIG. 5 is a perspective view showing relevant portions of the semiconductor device according to the first embodiment of the present disclosure.

FIG. 6 is a plan view of the semiconductor device according to the first embodiment of the present disclosure.

FIG. 7 is a bottom view of the semiconductor device according to the first embodiment of the present disclosure.

FIG. 8 is a front view of the semiconductor device according to the first embodiment of the present disclosure.

FIG. 9 is a plan view showing relevant portions of the semiconductor device according to the first embodiment of the present disclosure.

FIG. 10 is a bottom view showing relevant portions of the semiconductor device according to the first embodiment of the present disclosure.

FIG. 11 is a sectional view taken along line XI-XI in FIG. 10.

FIG. 12 is a sectional view taken along line XII-XII in FIG. 10.

FIG. 13 is a sectional view taken along line XIII-XIII in FIG. 10.

FIG. 14 is a sectional view taken along line XIV-XIV in FIG. 10.

FIG. 15 is a sectional view showing a use state of the semiconductor device according to the first embodiment of the present disclosure.

FIG. 16 is a sectional view showing a first variation of the semiconductor device according to the first embodiment of the present disclosure.

FIG. 17 is a sectional view showing a use state of the first variation of the semiconductor device according to the first embodiment of the present disclosure.

FIG. 18 is a perspective view showing a second variation of the semiconductor device according to the first embodiment of the present disclosure.

FIG. 19 is a sectional view showing the second variation of the semiconductor device according to the first embodiment of the present disclosure.

FIG. 20 is a perspective view showing a third variation of the semiconductor device according to the first embodiment of the present disclosure.

FIG. 21 is a sectional view showing the third variation of the semiconductor device according to the first embodiment of the present disclosure.

FIG. 22 is a sectional view showing a fourth variation of the semiconductor device according to the first embodiment of the present disclosure.

FIG. 23 is a plan view showing relevant portions of a semiconductor device according to a second embodiment of the present disclosure.

### DETAILED DESCRIPTION OF EMBODIMENTS

The following describes preferred embodiments of the present disclosure in detail with reference to the drawings.

The terms “first”, “second”, “third”, and the like in the present disclosure are used merely for identification, and are not intended to order these subjects.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, “A surface A faces (a first side or a second side) in a direction B” is not limited to the situation where the angle of the surface A with respect to the direction B is 90° and implies the situation where the surface A is inclined with respect to the direction B.

### First Embodiment:

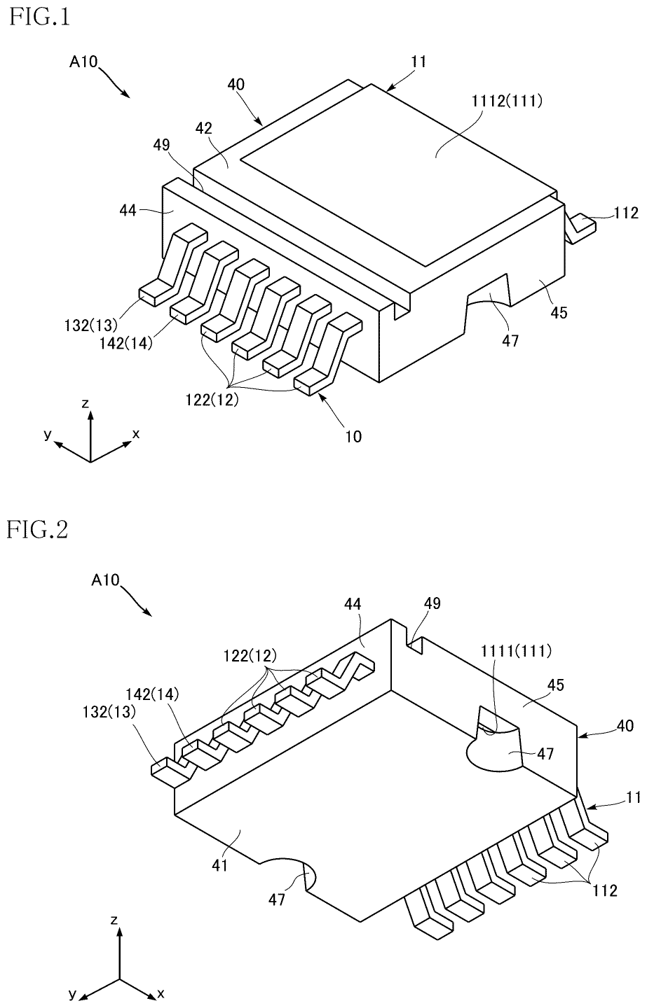

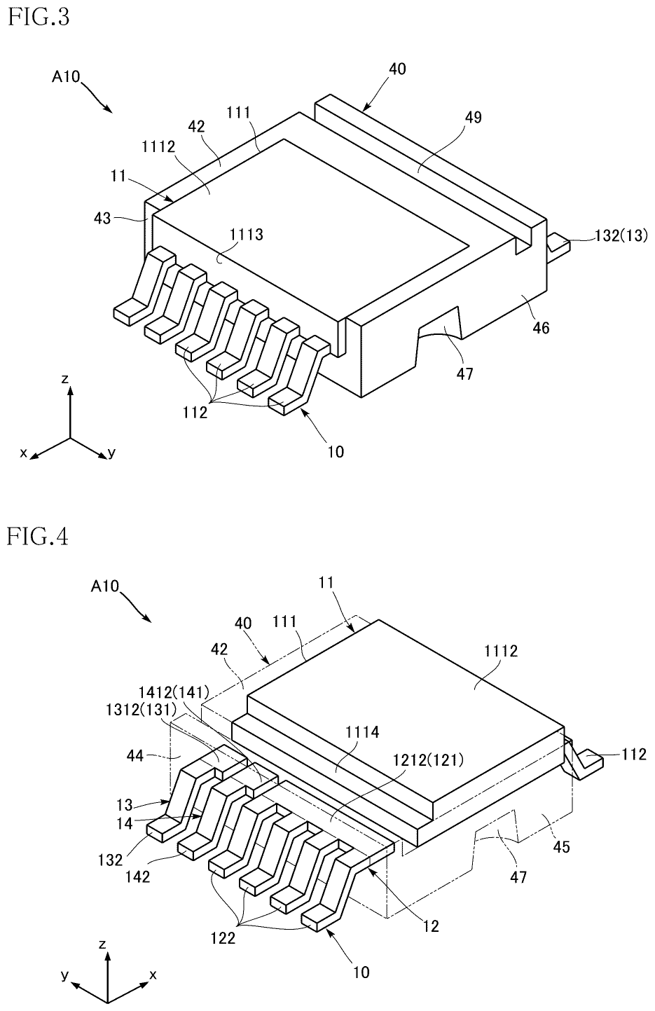

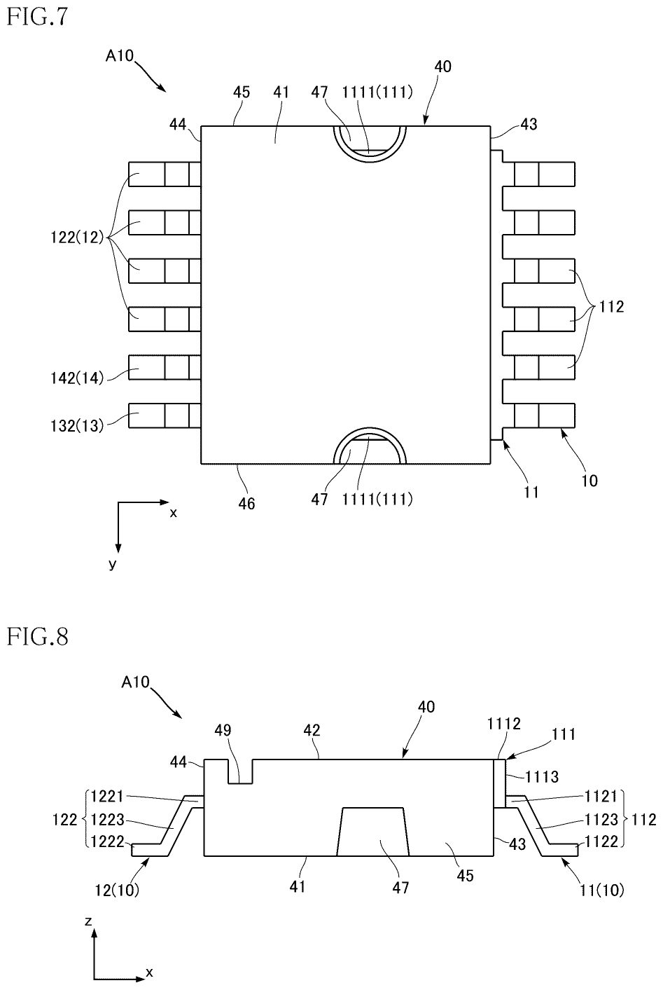

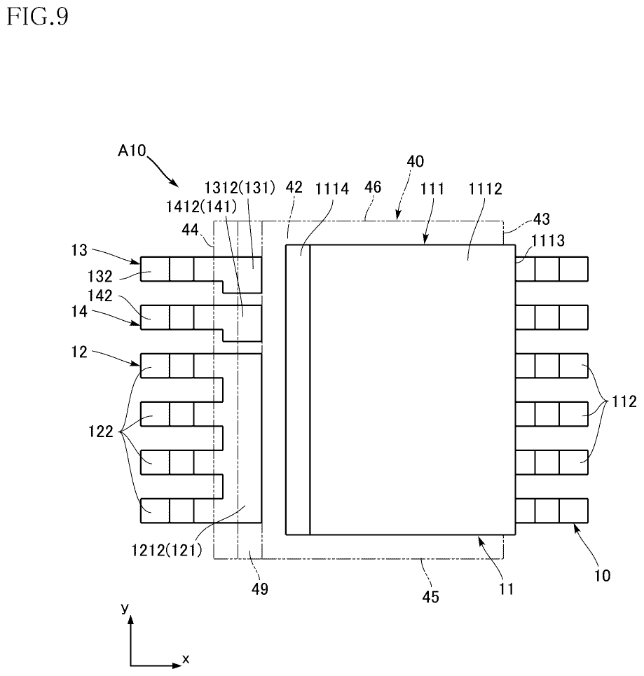

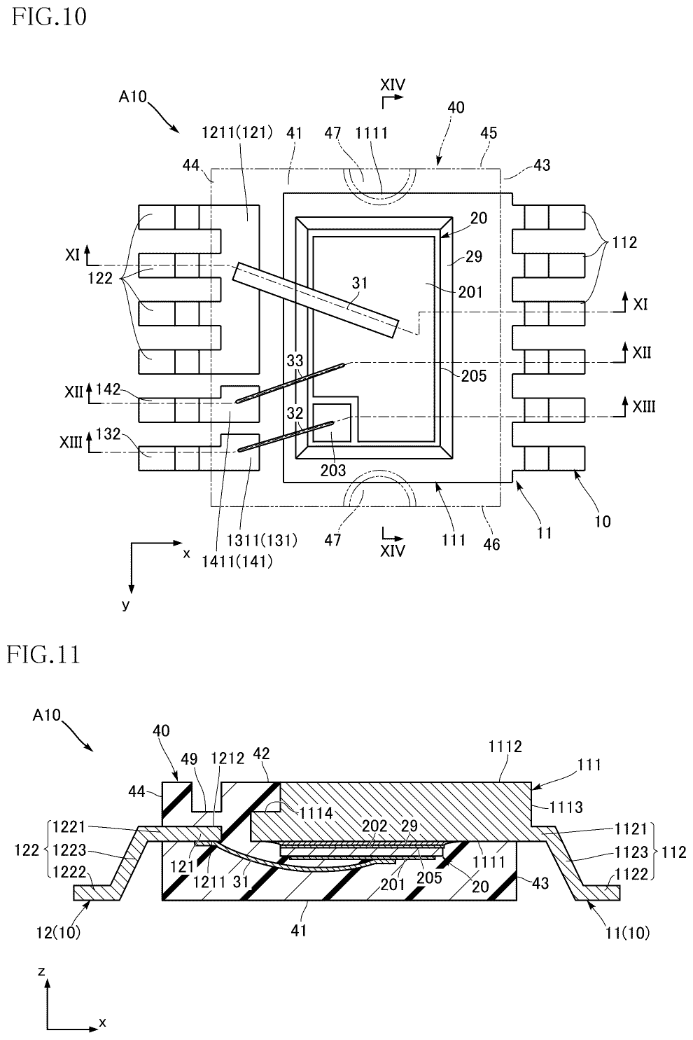

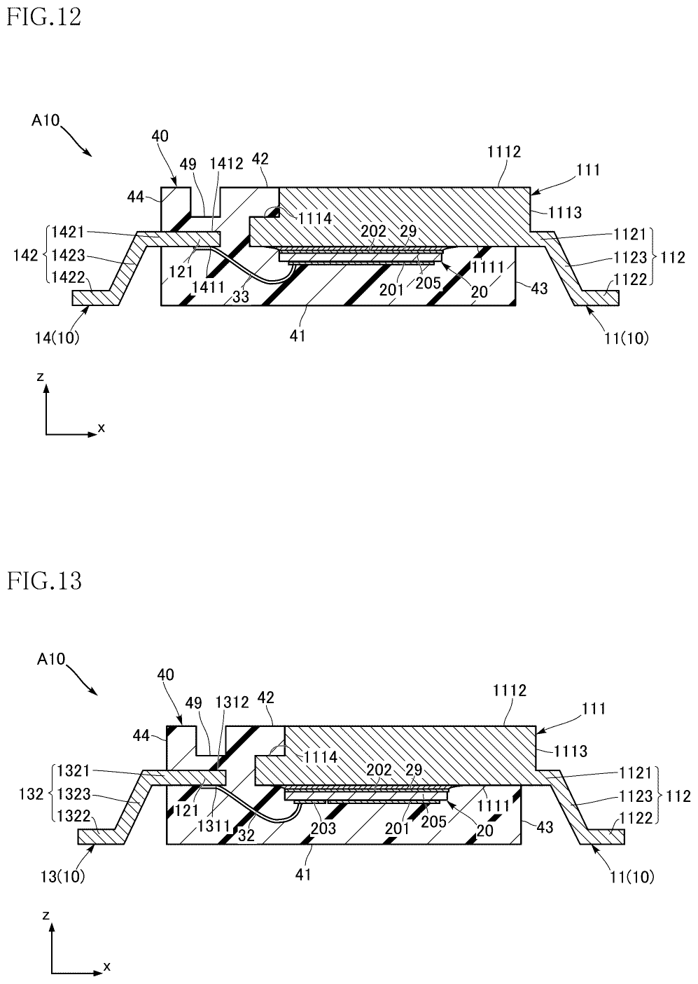

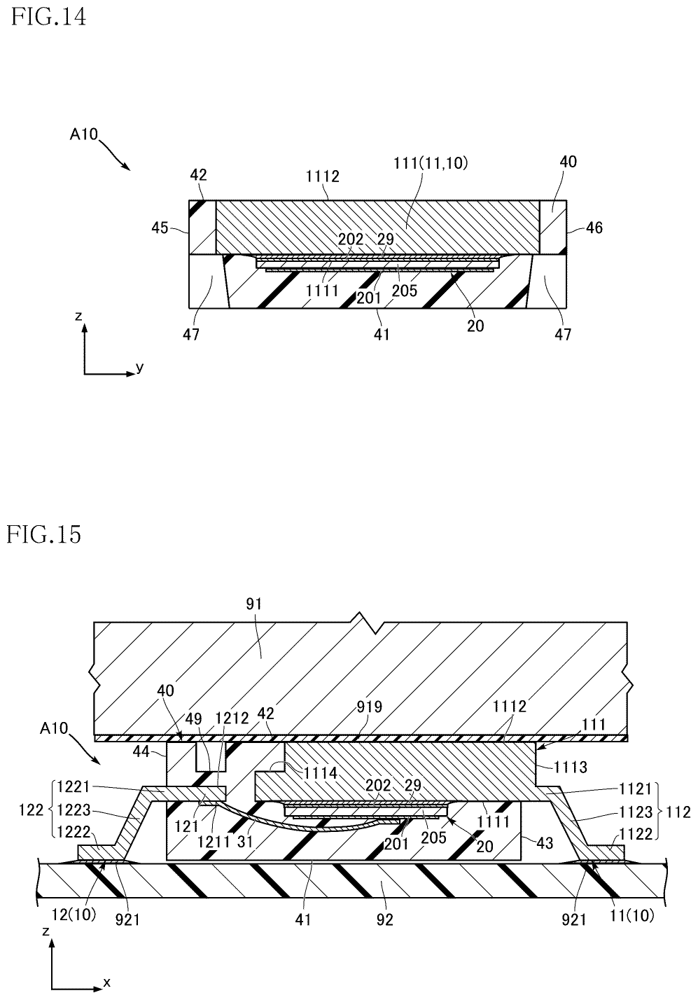

FIGS. 1 to 15 show a semiconductor device according to a first embodiment of the present disclosure. The semiconductor device A10 of the present embodiment includes a conductive member 10, a semiconductor element 20, connecting members 31, 32 and 33, and a sealing resin 40. In these figures, the z direction is an example of “thickness direction”, the x direction is an example of “first direction”, and the y direction is an example of “second direction”.

### Conductive Member 10:

The conductive member 10 is a member that forms conduction paths to the semiconductor element 20. The conductive member 10 of the present embodiment includes a first lead 11, a second lead 12, a third lead 13, and a fourth lead 14. The material of the first lead 11, the second lead 12, the third lead 13 and the fourth lead 14 is not limited and may include copper (Cu) or a copper alloy, for example. The first lead 11, the second lead 12, the third lead 13, and the fourth lead 14 may be plated with, for example, silver (Ag), nickel (Ni) or tin (Sn) at appropriate locations.

### First Lead 11:

As shown in FIGS. 1 to 15, the first lead 11 has a die pad portion 111 and plurality of first terminal portions 112. The die pad portion 111 has a first lead obverse surface 1111, a first lead reverse surface 1112, and a first lead side surface 1113. The first lead obverse surface 1111 faces a first side in the z direction. The first lead reverse surface 1112 faces a second side in the z direction. The semiconductor element 20 is mounted on the first lead obverse surface 1111.

The first lead side surface 1113 is located between the first lead obverse surface 1111 and the first lead reverse surface 1112 in the z direction and faces a first side in the x direction. The shape of the first lead side surface 1113 is not limited and is rectangular as viewed in the x direction in the illustrated example.

The die pad portion 111 of the present embodiment further has a first intermediate surface 1114. The first intermediate surface 1114 is located between the first lead obverse surface 1111 and the first lead reverse surface 1112 in the z direction and faces the first side (the same side as the side that the first lead obverse surface 1111 faces) in the z direction.

The shape of the die pad portion 111 is not limited. In the illustrated example, the die pad portion 111 is rectangular as viewed in the z direction. Also, the shape of the first lead obverse surface 1111 and the first lead reverse surface 1112 is not limited and is rectangular as viewed in the z direction in the illustrated example.

The first terminal portions 112 are arranged side by side in the y direction. Each of the first terminal portions 112 has a first portion 1121, a second portion 1122, and a third portion 1123.

The first portion 1121 is connected to a pad portion 111. The first portion 1121 extends from the first lead side surface 1113 of the die pad portion 111 toward the first side in the x direction, and is parallel to the xy-plane in the illustrated example. The shape of the first portion 1121 is not limited and is rectangular as viewed in the z direction in the illustrated example. In the present embodiment, the die pad portion 111 is larger than the first portion 1121 in size in the z direction. The first portion 1121 is spaced apart from the first lead reverse surface 1112 in the z direction and is in contact with the first lead obverse surface 1111 in the illustrated example. One face of the first portion 1121 is flush with the first lead obverse surface 1111.

The second portions 1122 is located on the first side in the z direction with respect to the first portion 1121. The second is used portion 1122 in surface-mounting the semiconductor device A10 to a circuit board or the like. The second portion 1122 extends along the x direction.

The third portion 1123 is interposed between the first portion 1121 and the two second portions 1122. The third portion 1123 extends from the first portion 1121 toward the first side in the z direction. In the illustrated example, the third portion 1123 is inclined with respect to the z direction (yz-plane). The shape of the third portion 1123 is not limited and is rectangular as viewed in the x direction in the illustrated example.

### Second Lead 12:

The second lead 12 is spaced apart from the first lead 11 (die pad portion 111) toward the second side in the x direction. The second lead 12 has a pad portion 121 and a plurality of second terminal portions 122.

The pad portion 121 has a second lead obverse surface 1211 and a second lead reverse surface 1212. The second lead obverse surface 1211 faces the first side in the z direction. The second lead reverse surface 1212 faces the second side in the z direction. The connecting member 31 is connected to the second lead obverse surface 1211. The shape of the pad portion 121 is not limited and is a rectangular shape elongated in the y direction in the illustrated example. The pad portion 121 is smaller than the die pad portion 111 as viewed in the z direction. The size of the pad portion 121 in the z direction is smaller than that of the die pad portion 111 and the same as that of the first terminal portion 112. In the illustrated example, the position of the second lead obverse surface 1211 in the z direction is the same as that of the first lead obverse surface 1111 of the die pad portion 111.

The second terminal portions 122 are arranged side by side in the y direction. Each of the second terminal portions 122 has a fourth portion 1221, a fifth portion 1222, and a sixth portion 1223.

The fourth portion 1221 is connected to the pad portion 121, extends from the pad portion 121 toward the second side in the x direction, and is parallel to the xy-plane in the illustrated example. The shape of the fourth portion 1221 is not limited and is rectangular as viewed in the z direction in the illustrated example.

The fifth portion 1222 is located on the first side in the z direction with respect to the fourth portion 1221. The is fifth portion 1222 used in surface-mounting the semiconductor device A10 to a circuit board or the like. The fifth portion 1222 extends along the x direction.

The sixth portion 1223 is interposed between the fourth portion 1221 and the fifth portion 1222. The sixth portion 1223 extends from the fourth portion 1221 toward the first side in the z direction. In the illustrated example, the sixth portion 1223 is inclined with respect to the z direction (yz-plane). The shape of the sixth portion 1223 is not limited and is rectangular as viewed in the x direction in the illustrated example.

### Third Lead 13:

The third lead 13 is spaced apart from the first lead 11 (die pad portion 111) toward the second side in the x direction. The third lead 13 is aligned with the second lead 12 in the y direction. The third lead 13 has a pad portion 131 and a third terminal portion 132.

The pad portion 131 has a third lead obverse surface 1311 and a third lead reverse surface 1312. The third lead obverse surface 1311 faces the first side in the z direction. The third lead reverse surface 1312 faces the second side in the z direction. The connecting member 32 is connected to the third lead obverse surface 1311. The shape of the pad portion 131 is not limited and is rectangular as viewed in the z direction in the illustrated example. The pad portion 131 is smaller than the pad portion 121 as viewed in the z direction.

The size of the pad portion 131 in the z direction is smaller than that of the die pad portion 111 and the same as that of the pad portion 121. In the illustrated example, the position of the third lead obverse surface 1311 in the z direction is the same as that of the first lead obverse surface 1111 of the die pad portion 111.

The third terminal portion 132 has a seventh portion 1321, an eighth portion 1322, and a ninth portion 1323.

The seventh portion 1321 is connected to the pad portion 131, extends from the pad portion 131 toward the second side in the x direction, and is parallel to the xy-plane in the illustrated example. The shape of the seventh portion 1321 is not limited and is rectangular as viewed in the z direction in the illustrated example.

The eighth portion 1322 is located on the first side in the z direction with respect to the seventh portion 1321. The eighth portion 1322 is used in surface-mounting the semiconductor device A10 to a circuit board or the like. The eighth portion 1322 extends along the x direction.

The ninth portion 1323 is interposed between the seventh portion 1321 and the eighth portion 1322. The ninth portion 1323 extends from the seventh portion 1321 toward the first side in the z direction. In the illustrated example, the ninth portion 1323 is inclined with respect to the z direction (yz-plane) . The shape of the ninth portion 1323 is not limited and is rectangular as viewed in the x direction in the illustrated example.

### Fourth Lead 14:

The fourth lead 14 is spaced apart from the first lead 11 (die pad portion 111) toward the second side in the x direction. The fourth lead 14 is located between the second lead 12 and the third lead 13 in the y direction. The fourth lead 14 has a pad portion 141 and a fourth terminal portion 142.

The pad portion 141 has a fourth lead obverse surface 1411 and a fourth lead reverse surface 1412. The fourth lead obverse surface 1411 faces the first side in the z direction. The fourth lead reverse surface 1412 faces the second side in The connecting member 33 is connected to the z direction. the fourth lead obverse surface 1411. The shape of the pad portion 141 is not limited and is rectangular as viewed in the z direction in the illustrated example. As viewed in the z direction, the pad portion 141 is smaller than the pad portion 121 and approximately the same size as the pad portion 131. The size of the pad portion 141 in the z direction is smaller than that of the die pad portion 111 and the same as that of the pad portion 121 and the pad portion 131. In the illustrated example, the position of the fourth lead obverse surface 1411 in the z direction is the same as that of the first lead obverse surface 1111 of the die pad portion 111.

The fourth terminal portion 142 includes a tenth portion 1421, an eleventh portion 1422, and a twelfth portion 1423.

The tenth portion 1421 is connected to the pad portion 141, extends from the pad portion 141 toward the second side in the x direction, and is parallel to the xy-plane in the illustrated example. The shape of the tenth portion 1421 is not limited and is rectangular as viewed in the z direction in the illustrated example.

The eleventh portion 1422 is located on the first side in the z direction with respect to the tenth portion 1421. The eleventh portion 1422 is used in surface-mounting the semiconductor device A10 to a circuit board or the like. The eleventh portion 1422 extends along the x direction.

The twelfth portion 1423 is interposed between the tenth portion 1421 and the eleventh portion 1422. The twelfth portion 1423 extends from the tenth portion 1421 toward the first side in the z direction. In the illustrated example, the twelfth portion 1423 is inclined with respect to the z direction (yz-plane). The shape of the twelfth portion 1423 is not limited and is rectangular as viewed in the x direction in the illustrated example.

### Semiconductor Element 20:

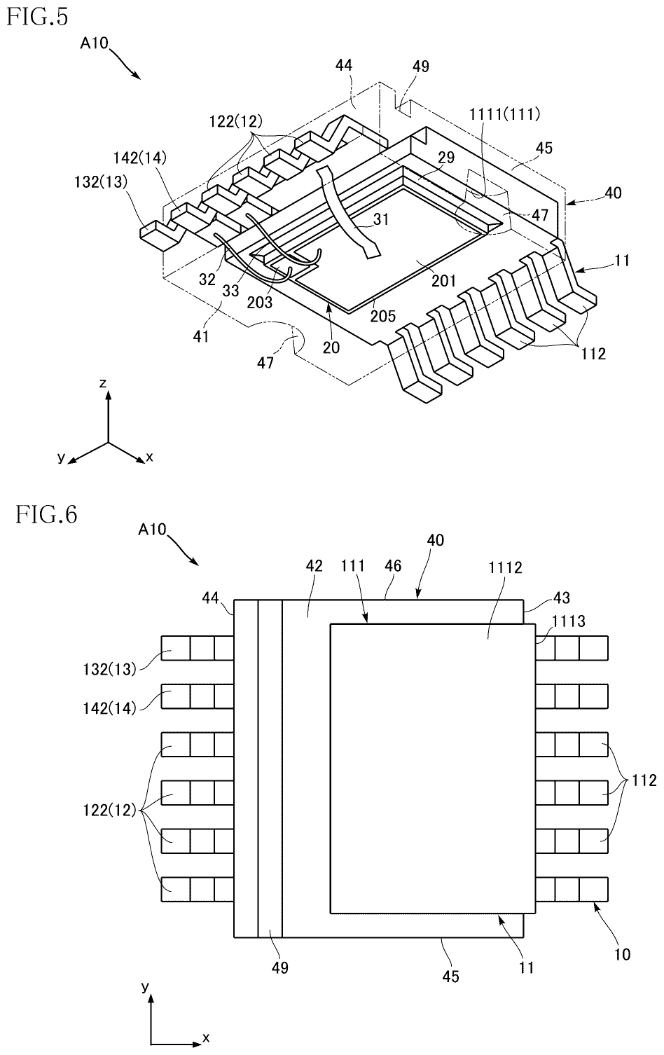

As shown in FIGS. 5 and 11 to 15, the semiconductor element 20 is mounted on the first lead obverse surface 1111 of the die pad portion 111. In the semiconductor device A10, the semiconductor element 20 is an n-channel MOSFET (Metal-Oxide-Semiconductor Field-Effect Transistor) of a vertical structure type. The semiconductor element 20 is not limited to a MOSFET. The semiconductor element 20 may be other transistors such as an IGBT (Insulated Gate Bipolar Transistor). The semiconductor element 20 may be a diode. The semiconductor element 20 has a semiconductor layer 205, a first electrode 201, a second electrode 202, and a third electrode 203.

The semiconductor layer 205 includes a compound semiconductor substrate. The main material of the compound semiconductor silicon carbide (SiC). substrate is Alternatively, silicon (Si) may be used as the main material of the compound semiconductor substrate.

The first electrode 201 is provided at a portion of the semiconductor layer 205 on the side (the first side) in the z direction that the first lead obverse surface 1111 of the die pad portion 111 of the first lead 11 faces. The first electrode 201 corresponds to the source electrode of the semiconductor element 20.

The second electrode 202 is provided at a portion of the semiconductor layer 205 that is opposite to the first electrode 201 in the z direction. The second electrode 202 faces the first lead obverse surface 1111 of the die pad portion 111 of the first lead 11. The second electrode 202 corresponds to the drain electrode of the semiconductor element 20. In the present embodiment, the second electrode 202 is bonded to the first lead obverse surface 1111 via a bonding layer 29. The bonding layer 29 is, for example, solder, silver (Ag) paste, sintered silver or the like.

The third electrode 203 is provided at a portion of the semiconductor layer 205 on the same side as the first electrode 201 in the z direction and spaced apart from the first electrode 201. The third electrode 203 corresponds to the gate electrode of the semiconductor element 20. As viewed in the z direction, the area of the third electrode 203 is smaller than the area of the first electrode 201.

### Connecting Members 31, 32 and 33:

The connecting member 31 is bonded to the first electrode 201 of the semiconductor element 20 and the second lead obverse surface 1211 of the pad portion 121 of the second lead 12. The material of the connecting member 31 is not limited and includes a metal such as aluminum (Al), copper (Cu) or gold (Au) . Also, the number of connecting members 31 is not limited, and a plurality of connecting members 31 may be provided. In the illustrated example, the connecting member 31 contains aluminum (Al) and is a flat strip-shaped member.

The connecting member 32 is bonded to the third electrode 203 of the semiconductor element 20 and the third lead obverse surface 1311 of the pad portion 131 of the third lead 13. In the illustrated example, the connecting member 32 contains gold (Au) and is a wire member thinner than the connecting member 31.

The connecting member 33 is bonded to the first electrode 201 of the semiconductor element 20 and the fourth lead obverse surface 1411 of the pad portion 141 of the fourth lead 14. In the illustrated example, the connecting member 33 contains gold (Au) and is a wire member thinner than the connecting member 31.

In the present embodiment, the first terminal portions 112 of the first lead 11 are drain terminals, the second terminal portions 122 of the second lead 12 are source terminals, the third terminal portion 132 of the third lead 13 is a gate terminal, and the fourth terminal portion 142 of the fourth lead 14 is a source sense terminal.

### Sealing Resin 40:

As shown in FIGS. 1 to 15, the sealing resin 40 covers the semiconductor element 20, the connecting members 31, 32 and 33, and a portion of each of the first lead 11, the second lead 12, the third lead 13 and the fourth lead 14. The sealing resin 40 has an electrically insulating property. The sealing resin 40 is made of a material containing a black epoxy resin, for example. The sealing resin 40 has a first resin surface 41, a second resin surface 42, a third resin surface 43, a fourth resin surface 44, a fifth resin surface 45, and a sixth resin surface 46.

The first resin surface 41 faces the same side (the first side) as the side that the first lead obverse surface 1111 of the die pad portion 111 of the first lead 11 faces in the z direction. The second resin surface 42 faces a side (the second side) opposite to the side that the first resin surface 41 faces in the z direction. The first lead reverse surface 1112 of the die pad portion 111 of the first lead 11 is exposed from the second resin surface 42. The second resin surface 42 and the first lead reverse surface 1112 are flush with each other.

The third resin surface 43 faces the first side in the x direction. The first lead reverse surface 1112 has a portion located on the first side in the x direction from the third resin surface 43 as viewed in the z direction. That is, a portion of the first lead reverse surface 1112 protrudes toward the first side in the x direction relative to the third resin surface 43. The first lead side surface 1113 of the die pad portion 111 is located on the first side in the x direction from the third resin surface 43.

The fourth resin surface 44 faces a side (the second side) opposite to the side that the third resin surface 43 faces in the x direction. In the present embodiment, the second terminal portions 122 of the second lead 12, the seventh portion 1321 of the third terminal portion 132 of the third lead 13, and the tenth portion 1421 of the fourth terminal portion 142 of the fourth lead 14 penetrate the fourth resin surface 44.

The fifth resin surface 45 and the sixth resin surface 46 face mutually opposite sides in the y direction.

In the illustrated example, the sealing resin 40 has a groove 49. The groove 49 is recessed from the second resin surface 42 in the z direction and extends along the y direction. The groove 49 reaches the fifth resin surface 45 and the sixth resin surface 46. The groove 49 is located between the first lead reverse surface 1112 and the fourth resin surface 44.

In the illustrated example, the sealing resin 40 also has two recesses 47. One of the recesses 47 is recessed from the first resin surface 41 and the fifth resin surface 45.

The other recess 47 is recessed from the first resin surface 41 and the sixth resin surface 46. Portions of the first lead obverse surface 1111 are exposed from the recesses 47. FIG. 15 shows the semiconductor device A10 in use. In this example of use, the semiconductor device A10 is surface-mounted on a circuit board 92. Specifically, the second portions 1122 of the first terminal portions 112, the fifth portions 1222 of the second terminal portions 122, the eighth portion 1322 of the third terminal portion 132, and the eleventh portion 1422 of the fourth terminal portion 142 are conductively bonded to a wiring pattern (not shown) of the circuit board 92 with solder 921, for example. Also, a heat sink 91 is placed to face the first lead reverse surface 1112 of the die pad portion 111. In the illustrated example, a sheet material 919 is disposed between the first lead reverse surface 1112 and the heat sink 91. The sheet material 919 may be an insulating sheet, for example.

Next, the effects of the semiconductor device A10 will be described.

As shown in FIG. 15, the first lead reverse surface 1112 is exposed from the second resin surface 42. This allows, for example, the heat sink 91 to be placed to face the first lead reverse surface 1112. The first lead reverse surface 1112 has a portion protruding toward the first side in the x direction relative to the third resin surface 43. This increases the area of the first lead reverse surface 1112 that faces the heat sink 91. As a result, the efficiency of heat dissipation from the semiconductor device A10 to the heat sink 91 can be increased. Also, the second portion 1122 is located on the first side in the z direction from the first portion 1121. Thus, the semiconductor device A10 can be surface-mounted to the circuit board 92 or the like using the second portions 1122.

The die pad portion 111 has a plurality of first terminal portions 112. This increases the mounting strength of the semiconductor device A10.

The size of the first portion 1121 in the y direction is smaller than the size of the die pad portion 111 in the y direction. This further enhances the holding of the first lead 11 by the sealing resin 40.

The die pad portion 111 is larger than the first portion 1121 in size in the z direction. With such a configuration, during the process of heat transfer from the semiconductor element 20 to the first lead reverse surface 1112, the heat can be transferred to a wider area in the x direction and the y direction. As a result, the heat from the semiconductor element 20 can be dissipated to the heat sink 91 or the like through a wider area of the first portion 1121, which enhances the heat dissipation efficiency.

One face of the first portion 1121 is flush with the first lead obverse surface 1111. This increases the distance from the first portion 1121 to the third resin surface 43 in the z direction and prevents the interference between the heat sink 91 or the like and the first terminal portion 112.

The sealing resin 40 is formed with the groove 49. This increases the distance along the surface of the sealing resin (hereinafter “creepage distance”) from the first lead 40 reverse surface 1112 to the second lead 12 (fourth portion 1221), the third lead 13 (seventh portion 1321) and the fourth lead 14 (tenth portion 1421).

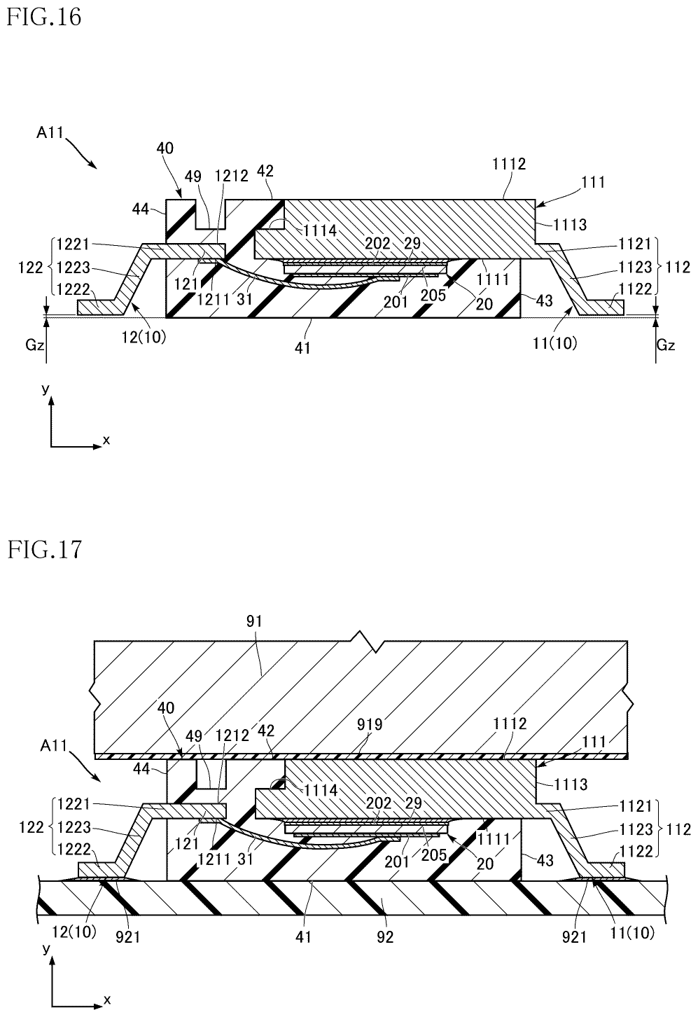

FIGS. 16 to 23 show other embodiments of the present disclosure. In these figures, the elements that are identical or similar to those of the above-described embodiment are denoted by the same reference signs as those of the above-described embodiments. Various parts of variations and embodiments may be selectively used in any appropriate combination as long as it is technically compatible.

### First Embodiment, First Variation:

FIGS. 16 and 17 show a first variation of the semiconductor device A10. The semiconductor device A11 of the present variation differs from the above-described example in relationship between the second portion 1122, the fifth portion 1222, the eighth portion 1322 and the eleventh portion 1422, and the first resin surface 41.

In the present variation, the second portion 1122, the fifth portion 1222, the eighth portion 1322 and the eleventh portion 1422 are located on the second side in the z direction (the side that the first lead reverse surface 1112 faces) from the first resin surface 41. The ends of the second portion 1122, the fifth portion 1222, the eighth portion 1322 and the eleventh portion 1422 on the first side in the z direction and the first resin surface 41 are spaced apart from each other by a distance Gz.

According to the present variation again, the semiconductor device A11 can be surface-mounted, and the same effects as those of the semiconductor device A10 are provided. Also, the first resin surface 41 protrudes toward the first side in the z direction by the distance Gz relative to the second portion 1122, the fifth portion 1222, the eighth portion 1322 and the eleventh portion 1422. Therefore, in the use state of the semiconductor device A11 shown in FIG. 17, when the heat sink 91 is pressed against the semiconductor device A11, the first resin surface 41 tends to come into contact with the circuit board 92. This reduces the likelihood that the force applied from the heat sink 91 acts on the first lead 11, the second lead 12, the third lead 13 and the fourth lead 14, or the semiconductor element 20.

### First Embodiment, Second Variation:

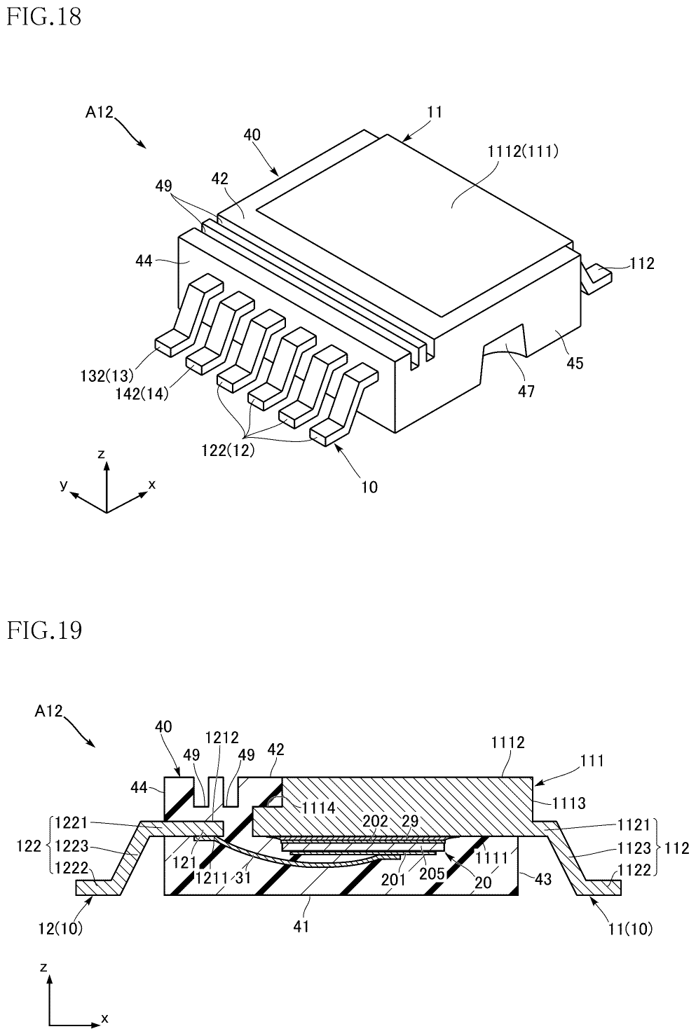

FIGS. 18 and 19 show a second variation of the semiconductor device A10. In the semiconductor device A12 of the present variation, the sealing resin 40 is provided with two grooves 49.

Each groove 49 extends in the y direction and reaches the fifth resin surface 45 and the sixth resin surface 46. The two grooves 49 are spaced apart from each other in the x direction.

According to the present variation again, the semiconductor device A12 can be surface-mounted, and the same effects as those of above-described examples are provided. Additionally, having two grooves 49 further increases the creepage distance between the first lead reverse surface 1112 and the second, the third and the fourth terminal portions 122, 132 and 142. As will be understood from the present variation, the number of grooves 49 is not limited.

### First Embodiment, Third Variation:

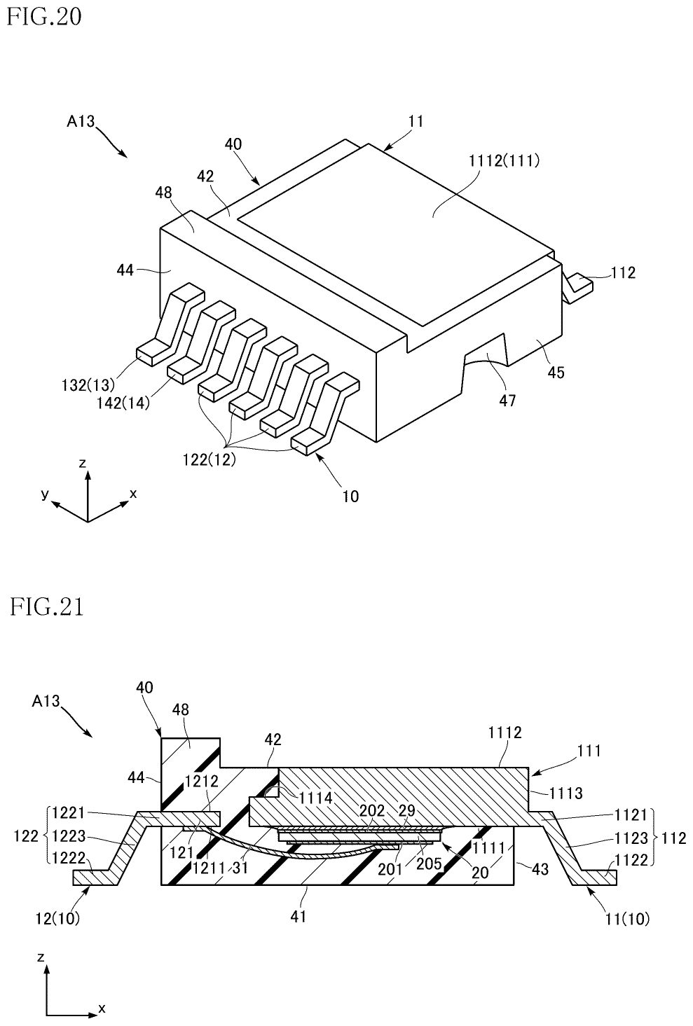

FIGS. 20 and 21 show a third variation of the semiconductor device A10. In the semiconductor device A13 of the present variation, the sealing resin 40 is provided with a protrusion 48.

The protrusion 48 protrudes from the second resin surface 42 toward the second side in the z direction. The protrusion 48 extends along the y direction and reaches the fifth resin surface 45 and the sixth resin surface 46. In the illustrated example, the protrusion 48 is located at the end on the second side in the x direction of the sealing resin 40 and in contact with the fourth resin surface 44.

According to the present variation again, the semiconductor device A13 can be surface-mounted. Additionally, having the protrusion 48 increases the creepage distance between the first lead reverse surface 1112 and the second, the third and the fourth terminal portions 122, 132 and 142.

### First Embodiment, Fourth Variation:

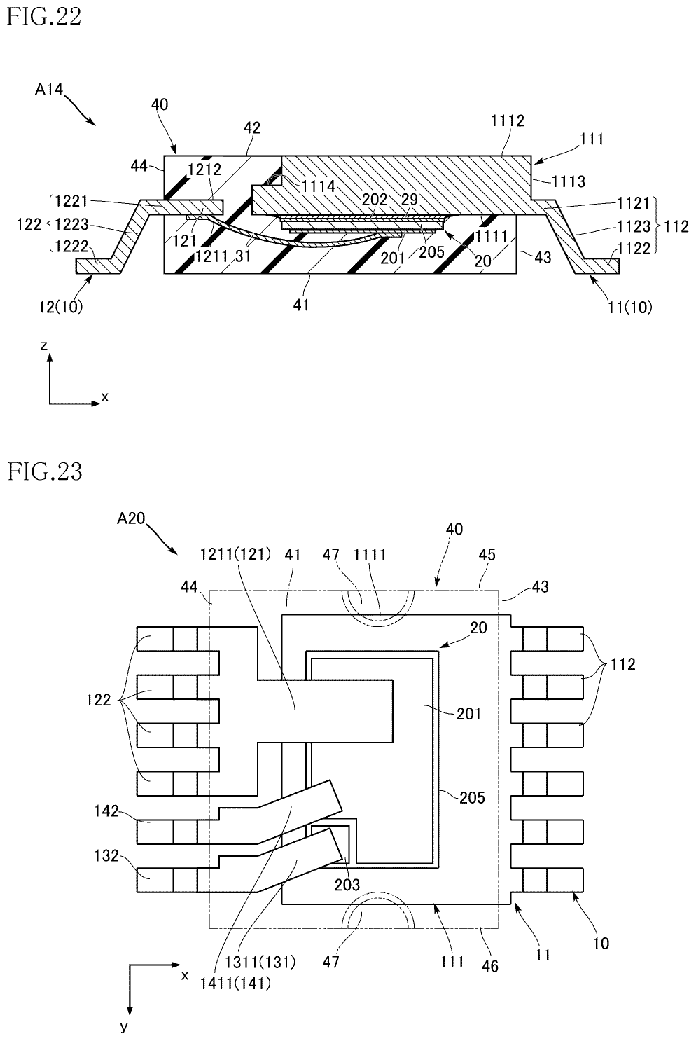

FIG. 22 shows a fourth variation of the semiconductor device A10. In the semiconductor device A14 of the present variation, the sealing resin 40 does not have the protrusion 48 and the groove 49 described above. According to the present variation again, the semiconductor device A14 can be surface-mounted. As will be understood from the present variation, the sealing resin 40 may not have the protrusion 48 and the groove 49.

### Second Embodiment:

FIG. 23 shows a semiconductor device according to a second embodiment of the present disclosure. The semiconductor device A20 of the present embodiment does not include the above-described connecting members 31, 32 and 33.

In the present embodiment, the second lead reverse surface 1212 of the pad portion 121 of the second lead 12 is conductively bonded to the first electrode 201 of the semiconductor element 20. The third lead reverse surface 1312 of the pad portion 131 of the third lead 13 is conductively bonded to the third electrode 203 of the semiconductor element 20. The fourth lead reverse surface 1412 of the pad portion 141 of the fourth lead 14 is conductively bonded to the first electrode 201 of the semiconductor element 20.

According to the present variation again, the semiconductor device A20 can be surface-mounted. As will be understood from the present embodiment, the specific configuration for conduction between the second, the third, and the fourth leads 12, 13 and 14 and the semiconductor element 20 is not limited.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

### Clause 1.

A semiconductor device comprising:
a semiconductor element;
a first lead including a die pad portion and a first terminal portion, the die pad portion including a first lead obverse surface which faces a first side in a thickness direction and on which the semiconductor element is mounted, and a first lead reverse surface facing a second side in the thickness direction; and
a sealing resin including a first resin surface facing the first side in the thickness direction, a second resin surface facing the second side in the thickness direction, and a third resin surface facing a first side in a first direction orthogonal to the thickness direction, the sealing resin covering the semiconductor element and a part of the die pad portion,
wherein the first lead reverse surface includes a portion exposed from the second resin surface and located on the first side in the first direction from the third resin surface as viewed in the thickness direction.

### Clause 2.

The semiconductor device according to clause 1, wherein the first lead reverse surface is flush with the second resin surface.

### Clause 3.

The semiconductor device according to clause 1 or 2, wherein the die pad portion includes a first lead side surface facing the first side in the first direction, and the first lead side surface is located on the first side in the first direction from the third resin surface.

### Clause 4.

The semiconductor device according to clause 3, wherein the first terminal portion includes a first portion extending outward from the third resin surface toward the first side in the first direction.

### Clause 5.

The semiconductor device according to clause 4, wherein the first terminal portion includes a second portion located on the first side in the thickness direction with respect to the first portion and used for mounting.

### Clause 6.

The semiconductor device according to clause 5, wherein the first terminal portion includes a third portion interposed between the first portion and the second portion.

### Clause 7.

The semiconductor device according to clause 6, wherein the third portion extends from the first portion toward the first side in the thickness direction.

### Clause 8.

The semiconductor device according to any one of clause 5 to 7, wherein the first lead includes plurality of first terminal portions.

### Clause 9.

The semiconductor device according to clause 8, wherein the plurality of first terminal portions are arranged side by side in a second direction orthogonal to the thickness direction and the first direction.

### Clause 10.

The semiconductor device according to any one of clauses 5 to 9, wherein the die pad portion is larger than the first portion of the first terminal portion in size in the thickness direction.

### Clause 11.

The semiconductor device according to clause 10, wherein one face of the first portion is flush with the first lead obverse surface.

### Clause 12.

The semiconductor device according to any one of clauses 5 to 11, further comprising:
a connecting member connected to the semiconductor element; and
a second lead located on a second side in the first direction with respect to the first lead and including a pad portion that includes a second lead obverse surface facing the first side in the thickness direction, wherein the connecting member is connected to the second lead obverse surface, and
the first lead obverse surface and the second lead obverse surface are at a same position in the thickness direction.

### Clause 13.

The semiconductor device according to clause 12, wherein the sealing resin includes a fourth resin surface facing the second side in the first direction, and
the second lead includes a second terminal portion including a fourth portion penetrating the fourth resin surface.

### Clause 14.

The semiconductor device according to clause 13, wherein the second terminal portion includes a fifth portion located on the first side in the thickness direction with respect to the fourth portion and used for mounting, and a sixth portion interposed between the fourth portion and the fifth portion.

### Clause 15.

The semiconductor device according to clause 14, wherein the second portion of the first terminal portion and the fifth portion of the second terminal portion are located on the second side in the thickness direction from the first resin surface.

### Clause 16.

The semiconductor device according to any one of clauses 1 to 15, wherein the sealing resin includes a groove recessed from the second resin surface in the thickness direction.

### Clause 17.

The semiconductor device according to any one of clauses 1 to 16, wherein the sealing resin includes a protrusion that protrudes from the second resin surface in the thickness direction.

### REFERENCE NUMERALS

A10, A11, A12, A13, A14, A20: Semiconductor device

10: Conductive member 11: First lead

12: Second lead 13: Third lead

14: Fourth lead 20: Semiconductor element

29: Bonding layer 30: Semiconductor element

31: Connecting member 32: Connecting member

33: Connecting member 40: Sealing resin

41: First resin surface 42: Second resin surface

43: Third resin surface 44: Fourth resin surface

45: Fifth resin surface 46: Sixth resin surface

47: Recess 48: Protrusion

49: Groove 52: Resin reverse surface

91: Heat sink 92: Circuit board

111: Die pad portion 112: First terminal portion

121: Pad portion 122: Second terminal portion

131: Pad portion 132: Third terminal portion

141: Pad portion 142: Fourth terminal portion

201: First electrode 202: Second electrode

203: Third electrode 205: Semiconductor layer

919: Sheet material 921: Solder

1111: First lead obverse surface

1112: First lead reverse surface

1113: First lead side surface

1114: First intermediate surface

1121: First portion 1122: Second portion

1123: Third portion 1211: Second lead obverse surface

1212: Second lead reverse surface 1221: Fourth portion

1222: Fifth portion 1223: Sixth portion

1311: Third lead obverse surface

1312: Third lead reverse surface

1321: Seventh portion 1322: Eighth portion

1323: Ninth portion 1411: Fourth lead obverse surface

1412: Fourth lead reverse surface 1421: Tenth portion

1422: Eleventh portion 1423: Twelfth portion

Gz: Distance

1. A semiconductor device comprising:
a semiconductor element;
a first lead including a die pad portion and a first terminal portion, the die pad portion including a first lead obverse surface which faces a first side in a thickness direction and on which the semiconductor element is mounted, and a first lead reverse surface facing a second side in the thickness direction; and
a sealing resin including a first resin surface facing the first side in the thickness direction, a second resin surface facing the second side in the thickness direction, and a third resin surface facing a first side in a first direction orthogonal to the thickness direction, the sealing resin covering the semiconductor element and a part of the die pad portion,
wherein the first lead reverse surface includes a portion exposed from the second resin surface and located on the first side in the first direction from the third resin surface as viewed in the thickness direction.

2. The semiconductor device according to claim 1, wherein the first lead reverse surface is flush with the second resin surface.

3. The semiconductor device according to claim 1, wherein the die pad portion includes a first lead side surface facing the first side in the first direction, and
the first lead side surface is located on the first side in the first direction from the third resin surface.

4. The semiconductor device according to claim 3, wherein the first terminal portion includes a first portion extending outward from the third resin surface toward the first side in the first direction.

5. The semiconductor device according to claim 4, wherein the first terminal portion includes a second portion located on the first side in the thickness direction with respect to the first portion and used for mounting.

6. The semiconductor device according to claim 5, wherein the first terminal portion includes a third portion interposed between the first portion and the second portion.

7. The semiconductor device according to claim 6, wherein the third portion extends from the first portion toward the first side in the thickness direction.

8. The semiconductor device according to claim 5, wherein the first lead includes plurality of first terminal portions.

9. The semiconductor device according to claim 8, wherein the plurality of first terminal portions are arranged side by side in a second direction orthogonal to the thickness direction and the first direction.

10. The semiconductor device according to claim 5, wherein the die pad portion is larger than the first portion of the first terminal portion in size in the thickness direction.

11. The semiconductor device according to claim 10, wherein one face of the first portion is flush with the first lead obverse surface.

12. The semiconductor device according to claim 5, further comprising:
a connecting member connected to the semiconductor element; and
a second lead located on a second side in the first direction with respect to the first lead and including a pad portion that includes a second lead obverse surface facing the first side in the thickness direction, wherein
the connecting member is connected to the second lead obverse surface, and
the first lead obverse surface and the second lead obverse surface are at a same position in the thickness direction.

13. The semiconductor device according to claim 12, wherein the sealing resin includes a fourth resin surface facing the second side in the first direction, and
the second lead includes a second terminal portion including a fourth portion penetrating the fourth resin surface.

14. The semiconductor device according to claim 13, wherein the second terminal portion includes a fifth portion located on the first side in the thickness direction with respect to the fourth portion and used for mounting, and a sixth portion interposed between the fourth portion and the fifth portion.

15. The semiconductor device according to claim 14, wherein the second portion of the first terminal portion and the fifth portion of the second terminal portion are located on the second side in the thickness direction from the first resin surface.

16. The semiconductor device according to claim 1, wherein the sealing resin includes a groove recessed from the second resin surface in the thickness direction.

17. The semiconductor device according to claim 1, wherein the sealing resin includes a protrusion that protrudes from the second resin surface in the thickness direction.
